(19) United States
(12) Patent Application Publication
(10) Pub. No.: US 2006/0258121 A1
(43) Pub. Date: Nov. 16, 2006

(54) METHOD OF BLOWING THE FUSE STRUCTURE

(76) Inventor: Bing-Chang Wu, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/908,404

(22) Filed: May 10, 2005

(51) Int. Cl. H01L 21/326

(52) U.S. Cl. 438/467

(57) ABSTRACT

The invention relates to a method of blowing the fuse structure. The fuse formed in a substrate comprises a conductor and an insulating layer, which has uniform thickness and is formed on the conductor. The method of blowing fuse structure comprises the steps of cutting the insulating layer formed on the conductor, exposing the surface of the conductor and producing insulation by a chemical reaction.

### BACKGROUND OF INVENTION

1. Field of the Invention

The present invention relates to a method of blowing the fuse structure, and more particularly, to remove the insulating layer of the fuse structure and expose the conductor, and perform a chemical reaction to make conductor become insulation.

2. Description of the Prior Art

As semiconductor processes become smaller and more complex, semiconductor components are influenced by impurities more easily. If a single metal link, a diode, or a MOS is broken down, the whole chip will be unusable. To treat this problem, fuses can be selectively blown for increasing the yield of IC manufacturing.

In general, fused circuits are redundant circuits of an IC. When defects are found in the circuit, fuses can be selectively blown for repairing or replacing defective circuits. For example, with memory, the top surface of the memory has fuse structures. When the memory cell, word line, or wire contains defects, fuses can be connected with other redundant memory cells, word lines or wires to replace the circuit.

Fuses are divided into two categories based on their operation: thermal fuse and eFuse. Thermal fuses can be cut by lasers and be linked by laser repair. The defective electrical connections of memory cells, word lines, or wires are replaced by new ones. An eFuse utilizes electro-migration for both forming open circuits and for repairing.

A thermal fuse is made of aluminum or copper. If a fuse structure is aluminum, the manufacturing process comprises depositing, photolithography and etching. If the fuse structure is copper, the manufacturing process comprises a dual damascence process. But, aluminum has bad step coverage, and as semiconductor processes become smaller than 0.13 μm, aluminum is utilized in multilevel interconnections less and less. Copper has no bad step coverage problem and has low resistance for decreasing RC delay, so copper is used to replace aluminum in multilevel interconnections. However, copper oxidizes easily, and how to manufacture copper fuse structures is an important issue in semiconductor processes.

### SUMMARY OF INVENTION

The present invention provides a method of blowing the fuse structure to solve the above-mentioned problems.

A fuse structure embodiment according to the present invention provides a method of blowing the fuse structure, the fuse structure formed in a substrate comprises at least a dielectric layer, a conductor on the surface of the dielectric layer, and an insulating layer, which has uniform thickness and is formed on the surface of the conductor, the method of blowing the fuse structure comprises removing the insulating layer formed on the surface of the conductor and exposing the conductor, and performing a thermal oxidation process on the exposed conductor such that the exposed conductor becomes an oxide.

Another embodiment of the fuse structure according to the present invention provides a method of blowing a fuse structure, the fuse structure formed in a substrate comprising a conductor and an insulating layer, which has uniform thickness and is formed on the surface of the conductor. The method of blowing the fuse structure comprises removing the insulating layer formed on the surface of the conductor and exposing the conductor, and performing a chemical reaction, the exposed conductor becoming insulation.

The fuse structure according to the present invention comprises the insulating layer formed on the conductor. Before the fuse structure is broken, the conductor connects electrically. Once the insulating layer formed on the conductor is removed, a chemical reaction is performed on the exposed conductor, and the conductor becomes an insulation for performing a repairing process. The present invention utilizes the characteristic of the conductor and only requires a simple manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of a vertical view of the fuse structure according to the present invention.

FIG. 2 is a diagram of a cross-section view of the fuse structure according to the present invention.

FIG. 3 is a diagram of a vertical view of the fuse structure with a removed insulating layer according to the present invention.

FIG. 4 is a diagram of a cross-section view of the fuse structure with the removed insulating layer according to the present invention.

FIG. 5 is a diagram of a vertical view of the fuse structure after performing the chemical reaction according to the present invention.

FIG. 6 is a diagram of a cross-section view of the fuse structure after performing the chemical reaction according to the present invention.

FIG. 7 is diagram showing the relationship between copper oxide thickness and heating time at different temperatures.

### DETAILED DESCRIPTION

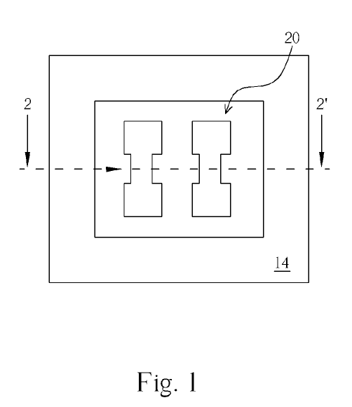

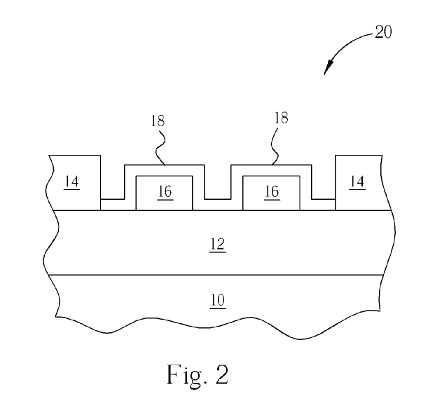

Please refer to FIGS. 1 and 2. FIG. 1 illustrates a vertical view of the fuse structure according to the present invention. FIG. 2 illustrates the cross-section view along 2-2′ in FIG. 1. A fuse structure 20 is formed in a dielectric layer 12 of a semiconductor chip 10. The fuse structure comprises a conductor 16 and an insulating layer 18 which has uniform thickness and is formed on the surface of the conductor 16. The dielectric layer 12 is made of silicon dioxide, silicon nitride or other dielectric materials such as inter metal dielectric (IMD). The conductor 16 is made by a multilevel interconnection process and is formed on the surface of the dielectric layer 12 with other multilevel interconnection layers (not shown). The insulating layer 18 is made of silicon oxide, silicon nitride, PSG and BPSG. Additionally, a passivation layer 1 4 like silicon nitride formed in the dielectric layer 12 is surrounded with the fuse structure 20. The passivation layer 14 protects the components and multilevel interconnection layers of the semiconductor chip 10. The insulating layer 18 and the passivation layer 14 could be made form the same material. Especially, when the conductor 16 is made by the traditional aluminum process, the insulating layer 18 and the passivation layer 14 could be made in the same time. That means we only need to make the passivation layer 14 on the dielectric layer 12 and the conductor 16.

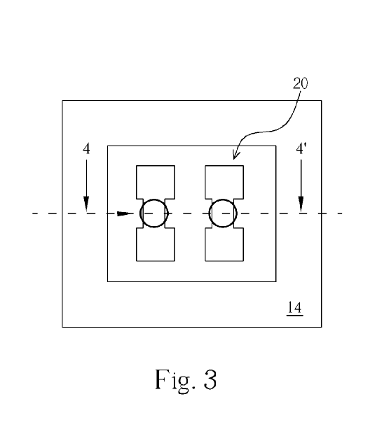

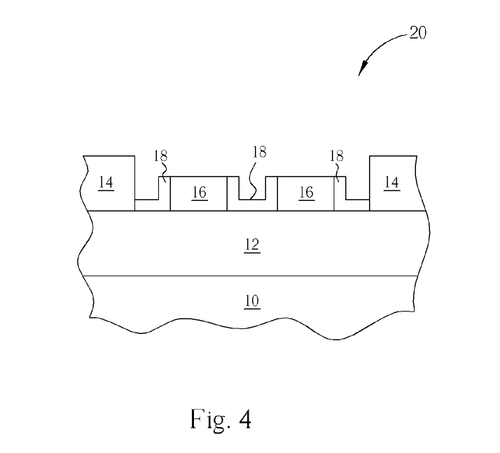

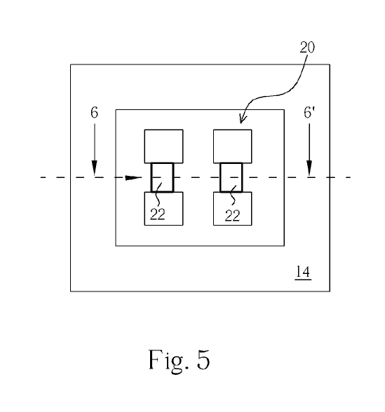

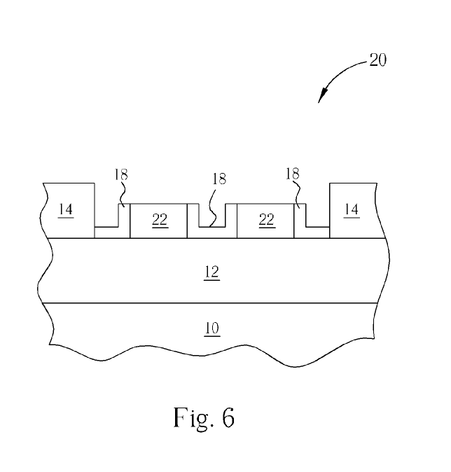

When the memory is produced finally and a partial memory cell, word line or wire is broken, the fuse structure according to the present invention will link other redundant circuits to replace the broken one. Please refer to FIGS. 3 to 6, which illustrate the method of blowing the fuse structure according to the present invention. FIG. 4 is a cross-section view along 4-4′ in FIG. 3 and FIG. 6 is a cross-section view along 6-6 in FIG. 5. FIG. 3 illustrates that the fuse structure 20 can be cut by a laser, can be oxidized, and can be repaired. For example, the insulating layer 18 is removed from the conductor 16, the conductor 16 is exposed to air, and a chemical reaction is performed such that and the conductor 16 becomes insulation 22 as FIGS. 5 and 6 show.

However, the conductor 16 is made by a multilevel interconnection process and is formed on the surface of the dielectric layer 12 like other interconnected layers. Aluminum and copper are common materials for multilevel interconnections. So, the conductor 16 becomes insulation 22 by thermal oxidation in the present invention. For example, the insulating layer 18 is cut by a laser, the conductor 16 is oxidized by hot air or oxygen, the conductor 16 becomes copper oxide or aluminum oxide, and the fuse structure 20 is broken and can't connect electrically anymore. The present invention can also utilize other gaseous matter to make the conductor 16 become other types of insulation.

In addition, the fuse structure according to the present invention provides the function of programming circuits for different functions. For reducing cost, every transistor is connected with each other by a metal link and memory array and plus a programmable linked component. After the semiconductor chip is finished, the standard chip can be customized using input data. When a 1 is transmitted into a PROM (Programmable ROM), the programmable linked component is blown open and becomes an open circuit (off-state) forever. Otherwise, the programmable linked component is closed and maintains an on-state when 0 is transmitted into the PROM. The fuse blowing process using input voltages is called programming.

In other words, the present invention can cut the fuse structure for programming. For example, when the standard memory chip is done, the standard memory chip has an etching process performed with the individual ROM code mask, and the insulating layer 18 formed on the conductor 16 is removed as shown in FIG. 4. Then, a chemical reaction is performed on the exposed conductor 16 and the conductor 16 becomes the insulation 22 completely as shown in FIGS. 5 and 6. Whether the fuse structure is maintained or is blown for programming depends on the manufacturer's needs.

The fuse structure 20 is made from a dual damascence process. The process comprises the step of forming a barrier layer, which is made of electric conductive material like Ti, Ta, TiN and TaN, to inhibit the copper diffuseness. If the conductor 16 is made of copper, when the fuse structure is blown, the barrier layer needs to become dielectric to break the circuit. For example, with the Ti barrier layer, the Ti needs to be oxidized to TiO2 to break the circuit. Besides, the other manufacture of the present invention does not form the barrier layer and can form the seed layer to electroplate copper directly. Then, we only need to remove the insulting layer 18, oxidize the copper conductor 16 and blow the fuse structure 20. In summary, the fuse structure 20 as shown in FIG. 2 is made by the dual damascence process without a barrier layer, etches the dielectric layer surrounding the conductor 16, and deposits the insulating layer 18 like silicon nitride, because copper oxidizes easily.

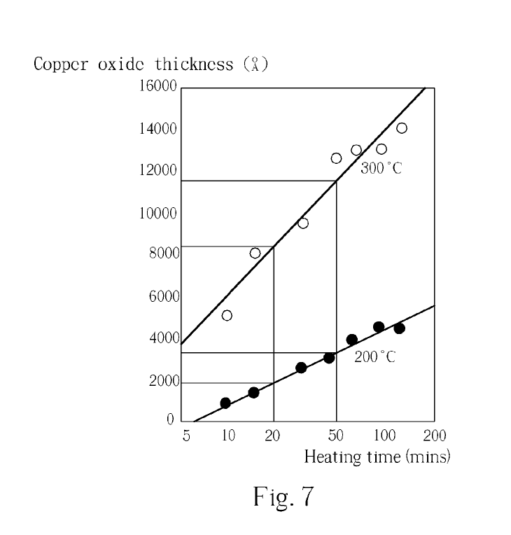

Please refer to FIG. 7. FIG. 7 is diagram showing the relationship between copper oxide thickness and heating time at different temperatures. In FIG. 7, when the temperature is 300 degrees centigrade, the copper oxide thickness is 8000 Å after twenty minutes, but when the temperature is 200 degrees centigrade, the copper oxide thickness is 2000 Å after twenty minutes. When the temperature is 300 degrees centigrade, the copper oxide thickness is almost 12000 Å after fifty minutes, but when the temperature is 200 degrees centigrade, the copper oxide thickness is about 4000 Å after fifty minutes. That means as the temperature becomes higher, the copper oxide thickness can be formed in shorter time. We can utilize the above idea in the present invention. The insulating layer 18 formed on the conductor 16 is removed, the conductor 16 is exposed, and thermal oxidation is performed for producing the insulation 22. By increasing the temperature of the thermal oxidation, the insulation 22 is produced in a shorter time.

Compared with the prior art, the fuse structure 20 according to the present invention comprises the insulating layer 18 formed on the conductor 16. Before the fuse structure 20 is broken, the conductor 16 connects electrically. The insulating layer 18 formed on the conductor 16 is removed, the chemical reaction is performed on the exposed conductor 16, and the conductor 16 becomes the insulation 22 for repairing. The present invention utilizes the characteristic of the conductor and can be manufactured simply.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of blowing the fuse structure, the fuse structure formed in a substrate comprising at least a dielectric layer, a conductor on the surface of the dielectric layer, and an insulating layer, which has uniform thickness and is formed on the surface of the conductor, the method of blowing the fuse structure comprising:
removing the insulating layer formed on the surface of the conductor and exposing the conductor; and
performing a thermal oxidation process on the exposed conductor such that the exposed conductor becomes an oxide.

2. The manufacture of the fuse structure of claim 1, wherein the insulating layer formed on the surface of the conductor is removed by a laser.

3. The manufacture of the fuse structure of claim 2, wherein the conductor is a copper conductor.

4. The manufacture of the fuse structure of claim 3, wherein the oxide is a copper oxide.

5. The manufacture of the fuse structure of claim 4, wherein the insulating layer is a dielectric layer.

6. The manufacture of the fuse structure of claim 1, wherein the step of removing the insulating layer formed on the surface of the conductor comprises completely removing the insulating layer formed on the surface of the conductor.

7. A method of blowing a fuse structure, the fuse structure formed in a substrate comprising a conductor and an insulating layer, which has uniform thickness and is formed on the surface of the conductor, the method of blowing the fuse structure comprising:
removing the insulating layer formed on the surface of the conductor and exposing the conductor; and
performing a chemical reaction, the exposed conductor becoming insulation.

8. The method of blowing the fuse structure of claim 7, wherein the insulating layer formed on the surface of the conductor is removed by a laser.

9. The method of blowing the fuse structure of claim 7, wherein the conductor is a copper conductor.

10. The method of blowing the fuse structure of claim 7, wherein the chemical reaction is a high temperature reaction and the oxide is copper oxide.

11. The method of blowing the fuse structure of claim 7, wherein the insulating layer is a dielectric layer.

12. The method of blowing the fuse structure of claim 7, wherein the step of removing the insulating layer formed on the surface of the conductor comprises completely removing the insulating layer formed on the surface of the conductor.

13. The method of blowing the fuse structure of claim 7, wherein the substrate is a semiconductor substrate and comprises at least a dielectric layer formed in the semiconductor substrate.

14. The method of blowing the fuse structure of claim 13, wherein the fuse structure is formed on the surface of the dielectric layer.
